(19) United States
(12) Patent Application Publication
(10) Pub. No.: US 2026/0063676 A1
(43) Pub. Date: Mar. 5, 2026

(54) COAXIAL SHUNT AND CURRENT DETECTION SYSTEM

(71) Applicant: Shenzhen Zhiyong Electronics Co., Ltd., Shenzhen (CN)

(72) Inventors: Xiaoming Fan, Shenzhen (CN); Jiawei Fan, Shenzhen (CN)

(21) Appl. No.: 18/975,700

(22) Filed: Dec. 10, 2024

(30) Foreign Application Priority Data
Sep. 4, 2024 (CN) 202411236532.5

(51) Int. Cl. G01R 15/14; G01R 19/00

(52) U.S. Cl. CPC G01R 15/146; G01R 19/0092

(57) ABSTRACT

Provided is a coaxial shunt, including an outer conductor, a resistor body, a central shaft conductor, and an insulating filler. The outer conductor, the resistor body, and the central shaft conductor each are of cylindrical structures and are coaxially arranged from outside to inside. An insulating connector is arranged between the outer conductor and the central shaft conductor. The insulating connector is mechanically connected to both the outer conductor and the center shaft conductor and/or the center shaft conductor and the resistor body are electrically flexibly connected. The coaxial shunt provided by the present disclosure ensures the stable and reliable resistor body by arranging the flexible electric connection mode between the insulating connector and/or the center shaft conductor and the resistor body. Further provided is a current detection system using the coaxial shunt.

### CROSS-REFERENCE TO RELATED APPLICATIONS

This application claims priority to Chinese Patent Application No. 202411236532.5, filed on September 04, 2024, which is hereby incorporated by reference in its entirety.

### TECHNICAL FIELD

The present disclosure relates to the technical field of high-frequency current detection, particularly to a coaxial shunt and a current detection system.

### BACKGROUND

A shunt (SHUNT) is a kind of resistor used for current. According to the Ohm's law, the voltage flowing through the resistor is equal to a product of the current and the resistance value. On the premise of the known resistance value, the current value may be calculated by detecting the voltage values at both ends of the resistor.

However, in the field of electronic measurement, it is often needed to measure high-frequency (greater than 100 MHz) current waveforms. If the current waveforms are measured with a conventional resistor, the shunt formed will generate great parasitic inductance, resulting in a relatively large measuring error of the current. In the prior art, for example, the Chinese patent CN118169447A discloses a coaxial shunt. A current flows into a resistor body through a first current conducting rod and then flows reversely through a conducting sleeve and flows out through a second current conducting rod, i.e., the current retraces when flowing through the coaxial shunt to counteract interference of a magnetic field.

Therefore, in the prior art, the coaxial shunt usually includes an outer conductor, a resistor body, and a center shaft conductor, and the center shaft conductor is connected to the resistor body. The center shaft conductor needs to be fixed to a conductor in a circuit through welding or threaded connection in a using process, which will be inevitably affected by an external force. The external force of the center shaft conductor received will be directly transferred to the resistor body, resulting in damage to the resistor body to different extents. Therefore, existing coaxial shunts all have the problem of poor stability and short service life. When a user mounts and fixes the coaxial shunt, as the center shaft conductor is connected to the inner resistor body, the center shaft conductor will be affected by the external force, which will form certain tensile force and twisting force to the resistor body. A slight influence will change the resistance value of the resistor body, resulting in the reduction of the measuring precision. Under severe circumstances, the resistor body will be directly damaged, so that the coaxial shunt cannot be used continuously.

### SUMMARY

The present disclosure provides a coaxial shunt and a current detection system to solve the above problems, so as to improve the high-frequency current detection stability and prolong the service life of the coaxial shunt.

Provided is a coaxial shunt, including an outer conductor, a resistor body, a central shaft conductor, and an insulating filler, where an accommodating cavity is formed inside the outer conductor, the outer conductor, the resistor body and the central shaft conductor each are of cylindrical structures and coaxially arranged from outside to inside, the center shaft conductor penetrates through the outer conductor, and both ends of the resistor body are electrically connected to the outer conductor and the center shaft conductor, respectively; the insulating filler is arranged in the accommodating cavity to fill gaps among the outer conductor, the resistor body, and the center shaft conductor; an insulating connector is arranged between the outer conductor and the central shaft conductor, and the insulating connector is mechanically connected to both the outer conductor and the center shaft conductor to fix relative positions between the center shaft conductor and the outer conductor, and transfers an external force of the center shaft conductor received to the outer conductor; and/or the center shaft conductor and the resistor body are flexibly electrically connected to buffer the external force of the center shaft received.

Furthermore, provided is a current detection system, including a detection device and a coaxial shunt. The coaxial shunt includes an outer conductor, a resistor body, a central shaft conductor, and an insulating filler, where an accommodating cavity is formed inside the outer conductor, the outer conductor, the resistor body and the central shaft conductor each are of cylindrical structures and coaxially arranged from outside to inside, the center shaft conductor penetrates through the outer conductor, and both ends of the resistor body are electrically connected to the outer conductor and the center shaft conductor, respectively; the insulating filler is arranged in the accommodating cavity to fill gaps among the outer conductor, the resistor body, and the center shaft conductor; an insulating connector is arranged between the outer conductor and the central shaft conductor, and the insulating connector is mechanically connected to both the outer conductor and the center shaft conductor to fix relative positions between the center shaft conductor and the outer conductor, and transfers an external force of the center shaft conductor received to the outer conductor; and/or the center shaft conductor and the resistor body are flexibly electrically connected to buffer the external force of the center shaft received; the detection device is electrically connected to the outer conductor and the center shaft conductor to detect the high-frequency current signal flowing through the outer conductor, the resistor body and the center shaft conductor.

Compared with the prior art, according to the coaxial shunt provided by the present disclosure, the insulating connector is arranged between the center shaft conductor and the outer conductor, and moreover, the relative positions of the outer conductor and the center shaft conductor are mechanically connected and fixed. When the coaxial shunt is used, in the operating process, the user will not damage the resistor body inside the outer conductor when pulling or twisting the center shaft conductor, thereby ensuring the stable and reliable resistor body. And/or the center shaft conductor and the resistor body are flexibly electrically connected to buffer the external force of the center shaft received, which may similarly ensure the stable and effective resistor body.

The current detection system using the coaxial shunt is also capable of prolonging the service life of the coaxial shunt and reducing the replacing frequency while ensuring detection of the precision of the high-frequency current signal, so that the detection cost is reduced.

### BRIEF DESCRIPTION OF DRAWINGS

To describe the technical solutions in the embodiments of the present disclosure more clearly, the following briefly describes the accompanying drawings required for describing the embodiments. Apparently, the accompanying drawings in the following description show merely some embodiments of the present disclosure, and a person of ordinary skill in the art may still derive other drawings from these accompanying drawings without making creative efforts.

FIG. 1 is a structural block diagram of a current detection system provided by the present application;

FIG. 2 is a three-dimensional schematic structural diagram of a coaxial shunt provided in an embodiment I of the present application;

FIG. 3 is a three-dimensional structural exploded view of the coaxial shunt provided in the embodiment I of the present application;

FIG. 4 is a sectional view of the coaxial shunt provided in the embodiment I of the present application;

FIG. 5 is a use state diagram of the coaxial shunt provided in the embodiment I of the present application in the current detection system;

FIG. 6 is a three-dimensional structural schematic diagram of the insulating connector shown in FIG. 3;

FIG. 7 is a three-dimensional structural schematic diagram of the center shaft conductor shown in the FIG. 3;

FIG. 8 is a sectional view of a coaxial shunt provided in an embodiment II of the present application;

FIG. 9 is a three-dimensional structural schematic diagram of the insulating connector shown in FIG. 8;

FIG. 10 is a three-dimensional structural schematic diagram of the center shaft conductor shown in the FIG. 8;

FIG. 11 is a sectional view of the insulating connector of the coaxial shunt provided in an embodiment III of the present application;

FIG. 12 is a sectional view of the coaxial shunt provided in the embodiment III of the present application;

FIG. 13 is a three-dimensional schematic structural diagram of a coaxial shunt provided in an embodiment VI of the present application;

FIG. 14 is a three-dimensional schematic structural diagram of a coaxial shunt provided in an embodiment V of the present application; and

FIG. 15 is a sectional view of a coaxial shunt provided in an embodiment VI of the present application.

### DESCRIPTION OF EMBODIMENTS

The following clearly and completely describes the technical solutions in the embodiments of the present disclosure with reference to the accompanying drawings in the embodiments of the present disclosure. Apparently, the described embodiments are some of the embodiments of the present disclosure rather than all of the embodiments. On the basis of the embodiments in the present disclosure, all other embodiments acquired by a person of ordinary skill in the art without making creative efforts fall within the scope of protection of the present disclosure.

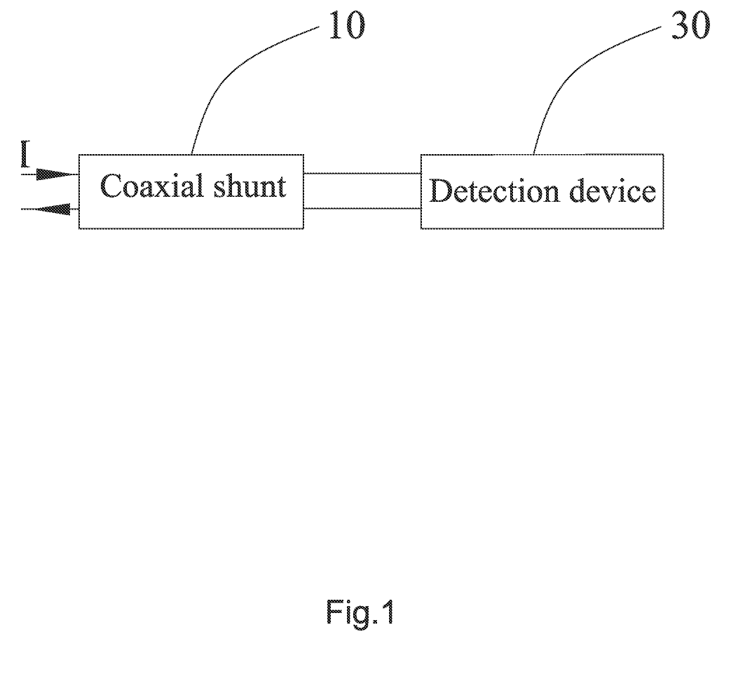

Referring to FIG. 1, a current detection system 100 provided by the present disclosure includes a coaxial shunt 10 and a detection device 30, where the detection device 30 is electrically connected to the coaxial shunt 10 and detects and displays a high-frequency current signal I flowing through the coaxial shunt 10. It is to be noted that the detection device 30 is a computer, an oscilloscope or another terminal device capable of being used for detecting and displaying current waveforms, which is not limited herein. The high-frequency current is mainly a current signal with a frequency greater than 100 MHz. Of course, the current detection system 100 may further detect a low-frequency signal. Compared with a common shunt, the coaxial shunt may reduce the influence of the parasitic inductance only when measuring the high-frequency signal, thereby improving the detection precision.

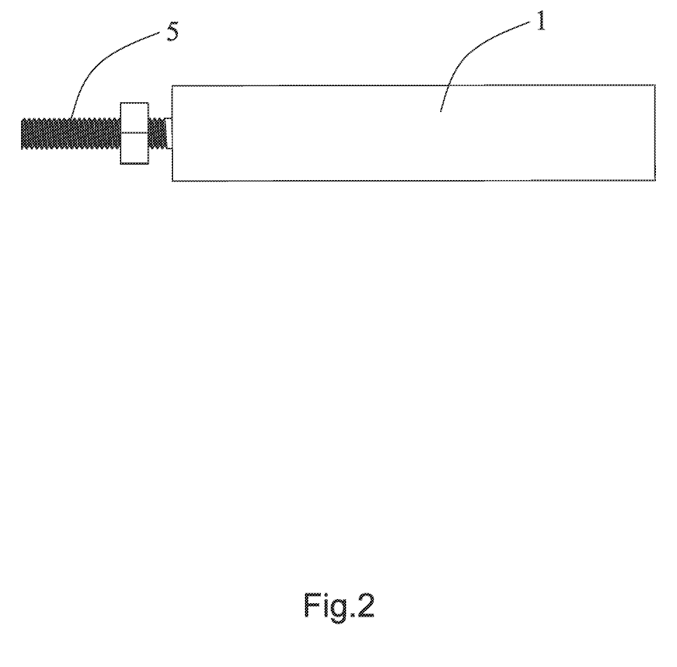

Continuously referring to FIGS. 2-4, FIGS. 2-4 are respectively a three-dimensional schematic structural diagram, an exploded view, and a sectional view of the coaxial shunt 10 provided in an embodiment I of the present application. The coaxial shunt 10 includes an outer conductor 1, a resistor body 3, a center shaft conductor 5, an insulating filler (not shown in the figures), and an insulating connector 7. An accommodating cavity 101 is formed inside the outer conductor 1, the resistor body 3 is received in the accommodating cavity 101, the outer conductor 1, the resistor body 3, and the central shaft conductor 5 each are of cylindrical structures and coaxially arranged from outside to inside, the center shaft conductor 5 penetrates through the outer conductor 1, and both ends of the resistor body 3 are electrically connected to the outer conductor 1 and the center shaft conductor 5, respectively. The center shaft conductor 5 and the outer conductor 1 are not directly connected but indirectly communicated through the resistor body 3. An end of the center shaft conductor 5 stretching out of the outer conductor 1 is connected externally to import or export the high-frequency current signal I.

Both ends of the resistor 3 are electrically connected to the outer conductor 1 and the center shaft conductor 5, respectively. The center shaft conductor 5 is communicated with the outer conductor 1 through the resistor 3. When the high-frequency current signal I flows from the center shaft conductor 5, it flows through the resistor 3 and is then exported by the outer conductor 1. When the high-frequency current signal I flows through the center shaft conductor 5 and the outer conductor 1, due to retracing flow, the influence of the magnetic field is eliminated, i.e., the influence of the parasitic inductance on detection of the high-frequency current detection is eliminated. Of course, the high-frequency current signal I may also flow through the outer conductor 1, and correspondingly, it flows through the resistor 3 and then flows out through the center shaft conductor 5.

The outer conductor 1 and the center shaft conductor 5 both are made of an easily conductive material such as a metal copper conductor. The resistor 3 is made of a material with a specific resistance value and good stability such as a carbon synthetic resistor, which is not limited herein. After the resistance value of the resistor body 3 and the voltage between the center shaft conductor 5 and the outer conductor 1 are specified, the high-frequency current signal I flowing through the coaxial shunt 10 may be simply calculated according to the Ohm's law.

The insulating filler is arranged in the accommodating cavity 101 to fill gaps among the outer conductor 1, the resistor body 3, and the center shaft conductor 5. As the outer conductor 1 and the center shaft conductor 5 are not directly connected, and the outer conductor 1, the resistor body 3, and the center shaft conductor 5 are coaxially arranged from outside to inside and there are a lot of gaps, by arranging the insulating filler which may fill the gaps, the positions among the outer conductor 1, the resistor body 3 and the center shaft conductor 5 are relatively stable. The insulating filler may be an existing insulating material. In the embodiment, it is preferably insulating glue, which may not only be used to fill but also fix the relative positions of the outer conductor 1, the resistor body 3, and the center shaft conductor 5.

The insulating connector 7 is mechanically connected to both the outer conductor 1 and the center shaft conductor 5 to fix relative positions between the center shaft conductor 5 and the outer conductor 1, and transfers an external force of the center shaft conductor 5 received to the outer conductor 1. The outer conductor 1 and the center shaft conductor 5 are electrically connected through the resistor body 3, and the center shaft conductor 5 and the resistor body 3 are usually fixed in a welding manner, so that the resistor body 3 is easily damaged during use. Through the insulating connector 7, although the outer conductor 1 and the center shaft conductor 5 are not in direct contact connection, the relative positions are fixed. When the coaxial shunt 10 is used, whether the center shaft conductor 5 is pulled or the center shaft conductor 5 I is rotated, the relative positions between the outer conductor 1 and the center shaft conductor 5 are invariable, so that the resistor body 3 will not be affected by the external force, i.e., will not be affected by the tensile force of the center shaft conductor 5 received or the twisting force due to rotation. Thus, the stability of the resistor body 3 is improved and the service life of the resistor body 3 is prolonged.

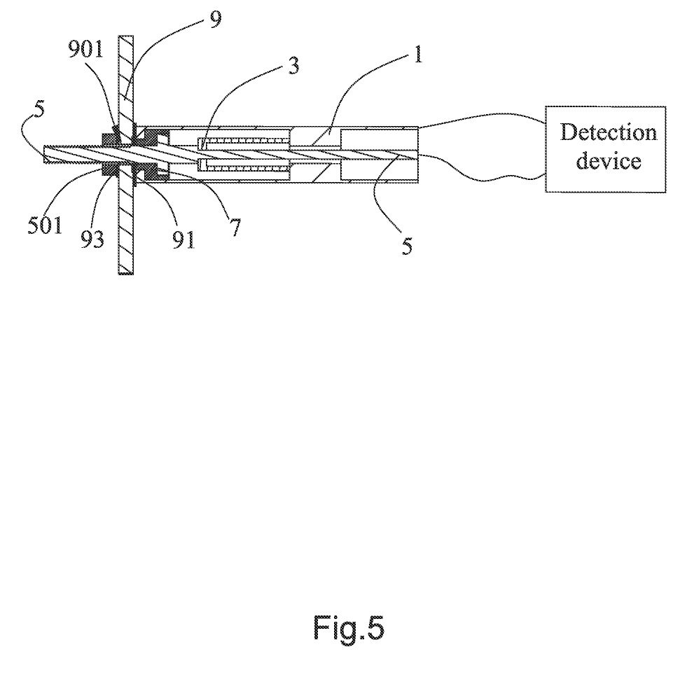

Continuously referring to FIG. 5, FIG. 5 is a use state diagram of the coaxial shunt 10 provided in the embodiment I of the present application in the current detection system 100. Taking the coaxial shunt 10 provided in the embodiment I as an example, the use of the current detection system 100 is described. The detection device 30 and the outer conductor 1 are electrically connected to the center shaft conductor 5 to detect the high-frequency current signal I flowing through the outer conductor 1, the resistor body 3, and the center shaft conductor 5. As shown in FIG. 5, the high-frequency current signal I is from a double-sided PCB9. A through hole 901 is formed in the double-sided PCB9. The center shaft conductor 5 penetrates through the double-sided PCB9 through the through hole 901 and matches with the nut 501 to fix the coaxial shunt 10 on the double-sided PCB9. The outer conductor 1 abuts against one side of the double-sided PCB9. A first conducting sheet 91 is arranged at an abutting position, so that the outer conductor 1 is electrically connected to the double-sided PCB9. The first conducting sheet 91 and the center shaft conductor 5 are arranged at an interval and they are not attached or connected to each other. The nut 501 abuts against the other side of the double-sided PCB9. A second conducting sheet 93 is arranged on the other side of the double-sided PCB9. The nut 501 abuts against the second conducting sheet 93, so that the center shaft conductor 5 is electrically connected to the second conducting sheet 93. The high-frequency current signal I is from the double-sized PCB9. The first conducting sheet 91 and the second conducting sheet 93 are respectively input and output ends of the high-frequency current signal I and are electrically connected to one end of the outer conductor 1 and one end of the center shaft conductor 5, respectively. The detection device 30 is electrically connected to the other end of the center shaft conductor 5 and the outer end of the outer conductor 1, thereby facilitating detection of the high-frequency current signal I. It is to be noted herein that besides the nut 501 connected to the second conducting sheet 93 and the center shaft conductor 5, a plurality of conductible nuts 501 may also be arranged to connect the outer conductor 1 and the first conducting sheet 91, so that the coaxial shunt 10 is mounted more stably. A conductible metal gasket may also be arranged between the outer conductor 1 and the first conducting sheet 91, so that the outer conductor 1 and the first conducting sheet 91 contact more sufficiently, which is not described repeatedly herein.

In the embodiment, when the coaxial shunt 10 is mounted, as the center shaft conductor 5 needs to penetrate through the double-sided PCB9 and is mounted and fixed with the nut 501, the center shaft conductor 5 is affected by both the tensile force and the twisting force. As the insulating connector 7 is mechanically connected to both the center shaft conductor 5 and the outer conductor 1, the tensile force and the twisting force of the center shaft conductor 5 will be transferred to the outer conductor 1. The relative positions between the outer conductor 1 and the center shaft conductor 5 will be invariable, so that the resistor body 3 will not affected by the external force.

It is to be noted herein that the mechanical connection, different from the existing coaxial shunt 10 which achieves fixation of the relative positions between the outer conductor 1 and the center shaft conductor 5 only through the insulating filler, achieves fixation of the relative positions between the outer conductor 1 and the center shaft conductor 5 in a manner that the mechanical structures of the insulating connector 7 matches with the structures of the outer conductor 1 and the center shaft conductor 5, so that the external force of the center shaft conductor 5 received may be transferred. In the embodiment, it is mainly designed in a manner that the mechanical structures clamp each other. Of course, in other embodiments, there may also be other mechanical connecting modes as long as the positions between the outer conductor 1 and the center shaft conductor 5 are fixed and they are not directly electrically connected. When the outer conductor 1 and the center shaft conductor 5 are mechanically connected and fixed, the insulating connector 7 made of the insulating material must be used without only using conductible connectors made of other materials, otherwise, the measuring structure will be affected severely.

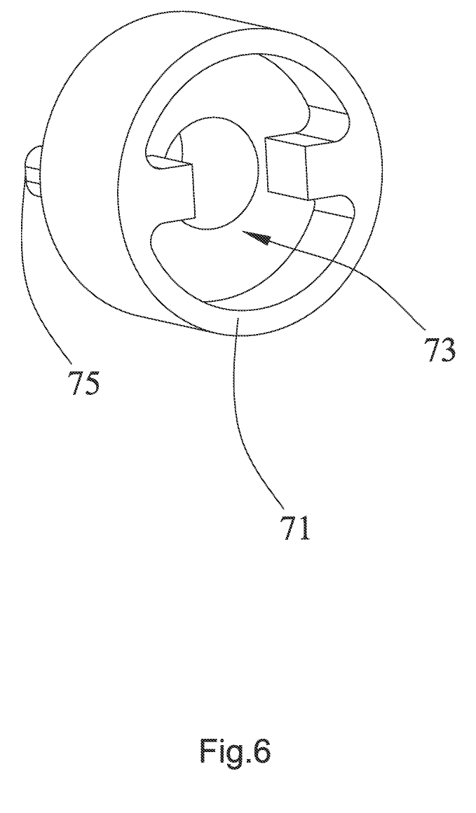

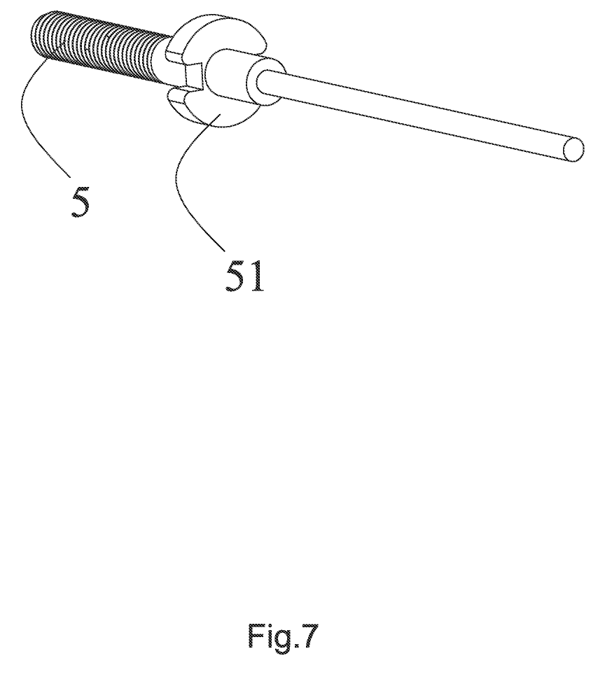

Of course, the structural arrangement of the insulating connector 7 may be diversified. In order to ensure the more stable mechanical connection between the center shaft conductor 5 and the outer conductor 1 and the insulating connector 7 to ensure transfer of the force, with continuous referring to FIGS. 6 and 7, FIGS. 6 and 7 are three-dimensional schematic structural diagrams of the insulating connector 7 and the center shaft conductor 5 provided in the embodiment I.

The center shaft conductor 5 is provided with a first boss 51, the insulating connector 7 is provided with a base 71 and a first groove 73, and the first groove 73 is formed relative to the first boss 51 and is formed at a side of the base 71 close to the resistor body 3. In order to ensure sufficient clamping between the center shaft conductor 5 and the insulating connector 7, the center shaft conductor 5 and the first groove 73 match with each other through the first boss 51 to achieve the clamping connection with the insulating connector 7. Furthermore, as the center shaft conductor 5 is mainly affected by the tensile force and the twisting force, the first boss 51 and the first groove 73 are clamped to ensure that when the center shaft conductor 5 rotates, the insulating connector 7 can transfer the twisting force of rotation. The first groove 73 is formed at a side of the base 71 close to the resistor 3, so that the base 71 and the first boss 51 match with each other, which may ensure that the insulating connector 7 may transfer the tensile force of the center shaft conductor 5 received. The overall structure is simple and practical and convenient to mount, without additionally increasing the volume of the coaxial shunt 10.

In the embodiment, the center shaft conductor 5 penetrates through the base 71, the first groove 73 matches with the first boss 51 in structural shape, and the first boss 51 is received in the first groove 73 and fits the base 71 sufficiently. It may be known from FIG. 6 that the base 71 in the insulating connector 7 provided in the embodiment I is of an annular structure; the center shaft conductor 5 and the base 71 are coaxially arranged; the first boss 51 includes two semi-annular structures and two recessed portions symmetrically arranged; and correspondingly, the structural shape of the first groove 73 is substantially identical to the overall shape of the first boss 51 with subtle differences in size. The two just match with each other, so that the first boss 51 is received in the first groove 73. Of course, the gap between the first boss 51 and the first groove 73 may also be filled by adding insulating glue, so that the first boss 51 and the first groove 73 are in clamping connection more stably, which ensures that the twisting force of the center shaft conductor 5 received may be effectively transferred.

It is to be noted here that in another embodiment, the structure of the first boss 51 may also be in another shape, and the structural shapes of the first groove 73 and the first boss 51 need not to be sufficiently identical, with the first boss 51 only abutting against the side wall of the first groove 73 on both sides of the rotating direction. The arrangement mode can ensure that the first boss 51 can match with the first groove 73 to effectively transfer the twisting force of the center shaft conductor 5 received. However, the first boss 51 and the base 71 must be in clamping connection through the first groove 73, otherwise, the twisting force cannot be transferred. The center shaft conductor 5 will still rotate relative to the outer conductor 1, resulting in damage to the resistor body 3. For example, the first boss 51 and the first groove 73 both are of intact annular structures, so the first boss 51 and the base 71 are not in clamping connection.

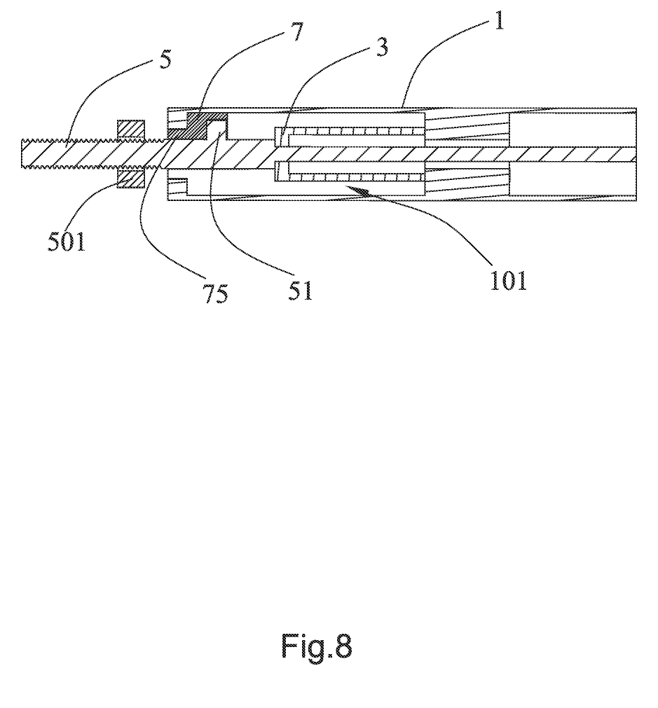

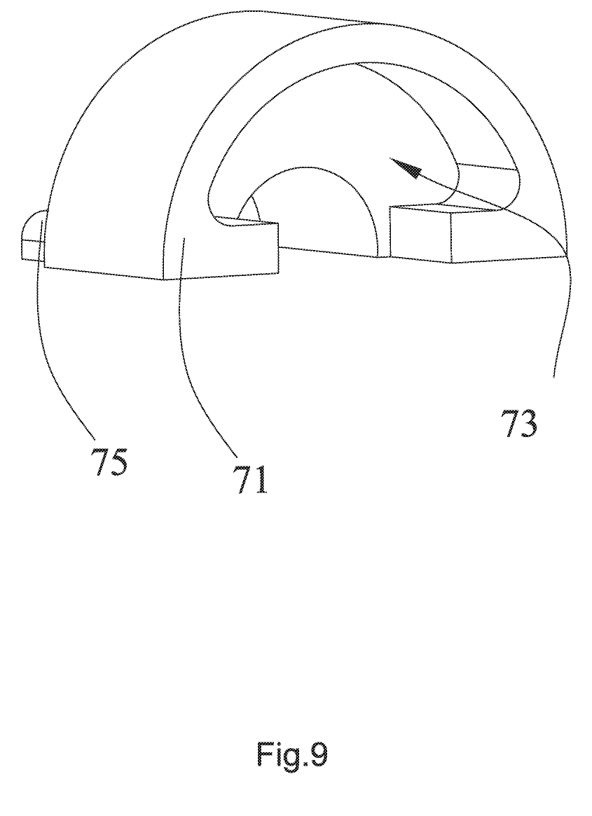

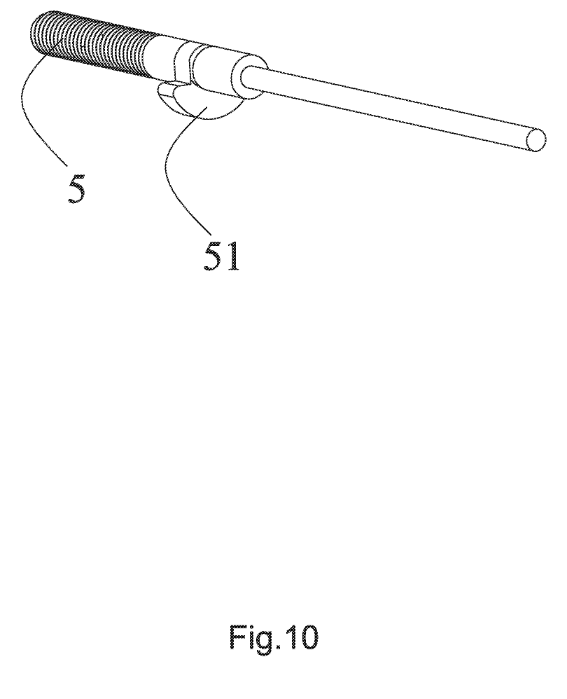

Continuously referring to FIGS. 8-10, FIGS. 8-10 are respectively the sectional view of the coaxial shunt 10 and the three-dimensional schematic structural diagrams of the insulating connector 7 and the center shaft conductor 5 provided in the embodiment II of the present application. The difference between the embodiment II and the embodiment I lies in that the first boss 51 and the insulating connector 7 are different in structure, which is illustrated particularly. The first boss 51 includes a semi-annular structure. The insulating connector 7 is arranged at one side of the center shaft conductor 5 and is arranged relative to the first boss 51. The insulating connector 7 is provided with the base 71 and the first groove 73 as well, but the center shaft conductor 5 does not penetrate through the base 71. The first groove 73 is formed still corresponding to the first boss 51 and is formed at a side of the base 71 close to the resistor body 3. The two match with each other in overall structure and can effectively transfer the twisting force received due to rotation of the center shaft conductor 5. Compared with the embodiment I, in the embodiment II, the use of materials is reduced, the production cost is reduced, and the user may make a choice according to an actual demand.

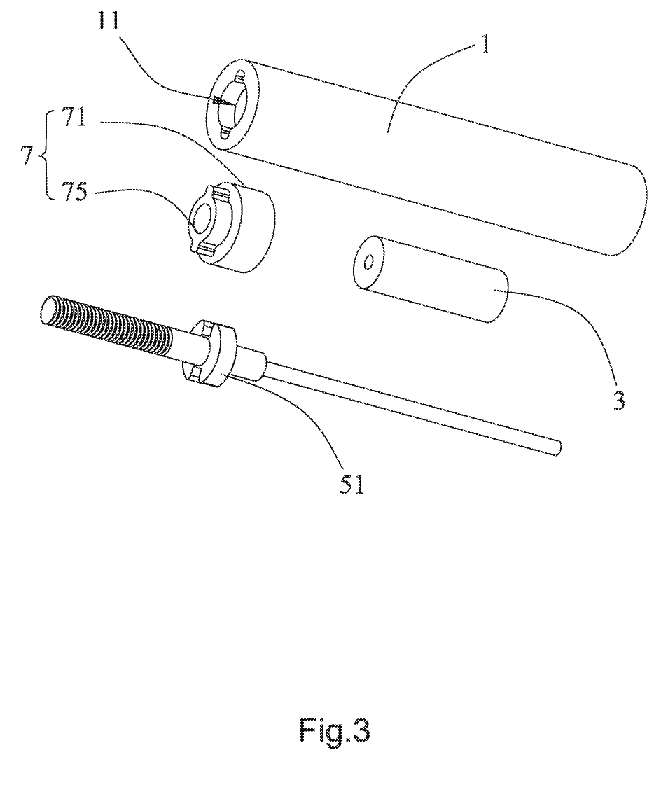

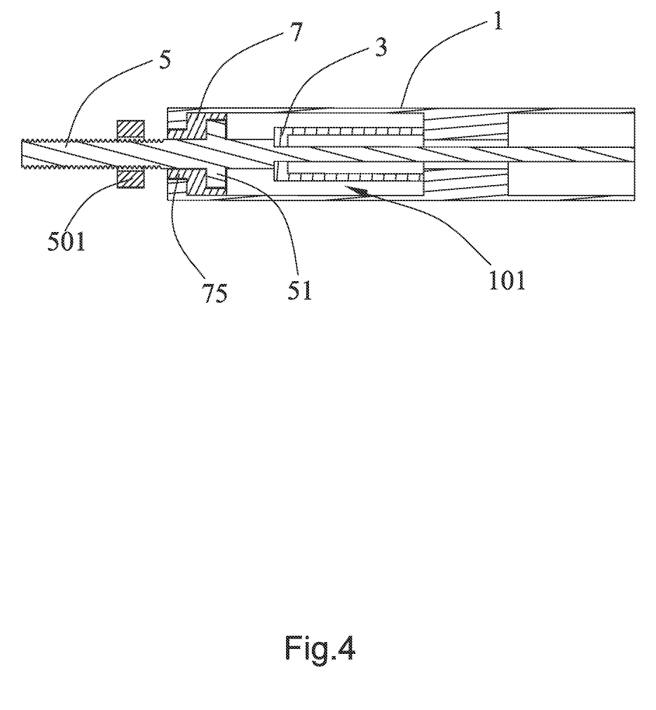

After the force of the center shaft conductor 5 received is transferred to the insulating connector 7, it is needed to consider how to transfer the force to the outer conductor 1 again. Referring to FIGS. 3, 4, and 6 again, the outer conductor 1 is provided with a clamping groove 11, the insulating connector 7 is provided a second boss 75, and the second boss 75 is arranged relative to the clamping groove 11 and is arranged at a side of the base 71 away from the resistor body 3. It may be seen from FIGS. 3 and 4 that the clamping groove 11 formed in the outer conductor 1 matches with the second boss 75 in shape and the two fit each other sufficiently. When the insulating connector 7 transfers the rotating twisting force, the twisting force may be transferred to the outer conductor 1 by way of clamping connection between the second boss 75 and the clamping groove 11. Furthermore, in the embodiment, as the second boss 75 is arranged at the side of the base 71 away from the resistor body 3, the overall area of the second boss 75 and the clamping groove 11 is smaller than that of the base 71. Therefore, when the insulating connector 7 transfers the tensile force, the base 71 fits the outer conductor 1 sufficiently to transfer the tensile force to the outer conductor 1. It is to be noted herein that in another embodiment, the second boss 75 may also be arranged at a peripheral side of the base 71 to achieve mutual match between the second boss 75 and the clamping groove 11 as well, so as to transfer the force by the insulating connector 7.

Similarly, the second boss 75 and the outer conductor 1 must be in clamping connection through the first groove 73, otherwise, the twisting force cannot be transferred. The center shaft conductor 5 will still rotate relative to the outer conductor 1, resulting in damage to the resistor body 3. For example, the second boss 75 and the clamping groove 11 both are of intact annular structures, so the second boss 75 and the outer conductor 1 are not in clamping connection.

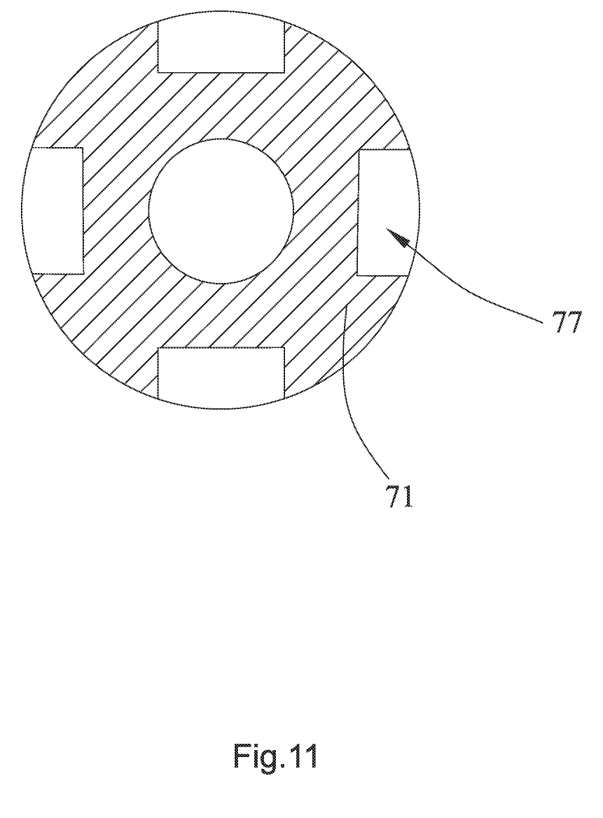

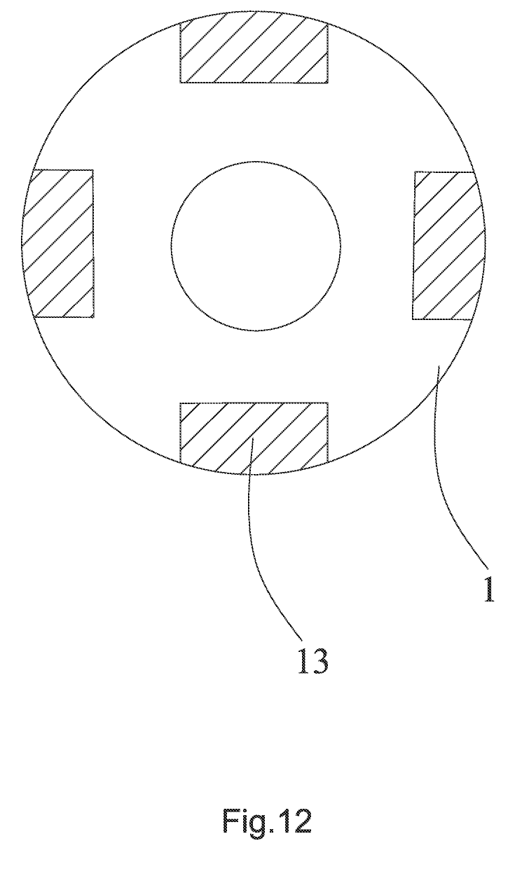

In addition, referring to FIGS. 11 and 12, FIGS. 11 and 12 are respectively the sectional views of the insulating connector 7 and the outer conductor 1 in the coaxial shunt 10 provided in the embodiment III of the present application. The difference between the embodiment III and the embodiment I lies in that the outer conductor 1 and the insulating connector 7 are different in structure. In the embodiment III, the outer conductor 1 is provided with a flange 13, the insulating connector 7 is provided with a second groove 77, and the second groove 77 is formed relative to the flange 13. The base 71 is provided with the second groove 77 to match with the flange 13, so that the base 71 fits the flange 13 sufficiently, which may similarly transfer the tensile force and the twisting force. Of course, the structures of the second groove 77 and the second flange 13 are not further limited herein. In order for more sufficient fitting to better transfer the force, the base 71 may be uniformly provided with the plurality of second grooves 77 circumferentially. Similarly, the flange 13 may also be correspondingly arranged.

In the embodiment I, the embodiment II, and the embodiment III, the center shaft conductors 5 all are of columnar structures. A thread is arranged at a side of the center shaft conductor 5 stretching out of the outer conductor 1 and matches with the nut 501 for fixing the position. As shown in FIG. 5, the coaxial shunt 10 is conveniently fixed at the position of the double-sided PCB9 for use. The arrangement mode is simple and convenient and the coaxial shunt 10 may be detached and mounted anytime. Moreover, the center shaft conductor 5 and the second conducting sheet 93, and the outer conductor 1 and the first conducting sheet 91 are stably connected, which are not easily interfered by the surrounding environment.

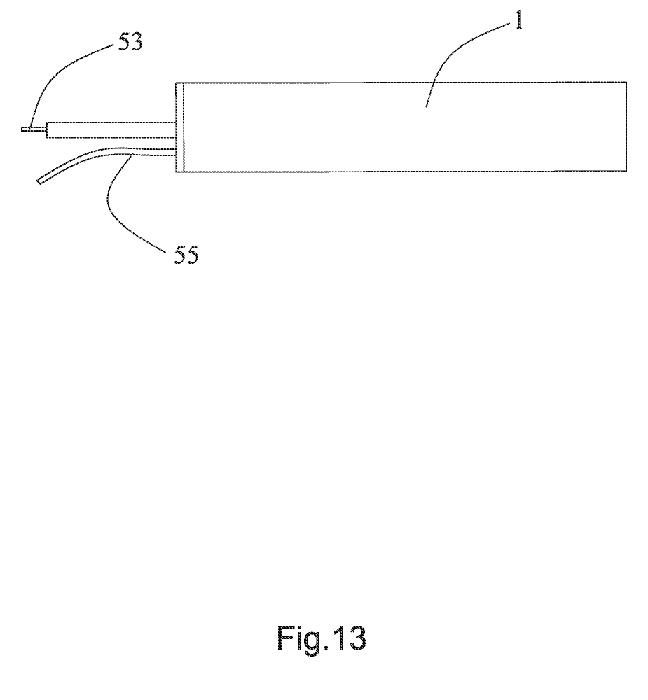

Continuously referring to FIG. 13, FIG. 13 is a three-dimensional schematic structural diagram of a coaxial shunt 10 provided in an embodiment VI of the present application. The uppermost difference between the embodiment IV and the above embodiments lies in that in the above embodiments, the center shaft conductor 5 is connected to the double-sided PCB9 by way of threaded connection in columnar structure to measure the high-frequency current signal I; in the embodiment IV, the center shaft conductor 5 is provided with the first current conducting rod 33, the outer conductor 1 is provided with the second current conducting rod 35, the first current conducting rod 33 is arranged at a side of the center shaft conductor 5 stretching out of the outer conductor 1, and the second current conducting rod 35 and the first current conducting rod 33 are arranged at an interval at the same side of the outer conductor 1 and each are slender conductors. The high-frequency current signal I may be measured through the first current conducting rod 33 and the second current conducting rod 35 as well. The first conducting rod 33 and the second conducting rod 35 need to be fixed in a welding manner at input and output ends of the high-frequency current signal I. The arrangement mode of the embodiment IV is wider in the applicable scene and measurement may also be performed without the double-sized PCB9. Similarly, in the embodiment IV, it is also needed to arrange the insulating connector 7. As the first conducting rod 33 needs to be mounted and fixed, it will also be affected by the tensile force and the rotating twisting force. The problem of damage to the resistor body 3 may also be solved by the insulating connector 7.

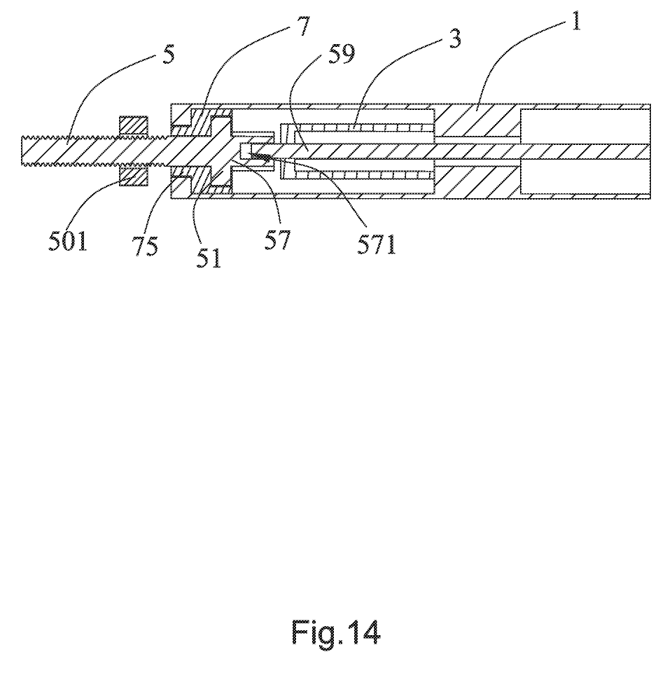

In order to ensure that the resistor body 3 will not be affected by the center shaft conductor 5, the center shaft conductor 5 and the resistor body 3 may also be connected by way of flexible electric connection. Specifically, continuously referring to FIG. 14, FIG. 14 is a sectional view of the coaxial shunt 10 provided in an embodiment V of the present application. The center shaft conductor 5 includes a first rod 57 and a second rod 59, the first rod 57 being mechanically connected to the insulating connector 7 and one end of the first rod 57 stretching out of the outer conductor 1. The second rod 59 penetrates through the resistor body 3, is flexibly electrically connected to the first rod 57, and is electrically connected to the resistor body 3. Compared with other embodiments where the center shaft conductor 5 is integrally arranged, in the coaxial shunt 10 provided in the embodiment V, the insulating connector 7 may be more easily mounted and clamped relative to the center shaft conductor 5 and the outer conductor 1 as the center shaft conductor 5 is arranged as the first rod 57 and the second rod 59 that may be mounted separately. The first rod 57 and the second rod 59 may be mounted separately, and in the mounting process, they will not be in contact with the resistor body 3 many times, so that the resistor body 3 may be protected as much as possible.

It is to be noted herein that the flexible electric connection refers to electric connection between two conducting materials rather than rigid connection to transfer the force directly, but has a certain buffer effect. In the embodiment, the flexible electric connection refers to electric connection between the first rod 57 and the second rod 59, which are not fixed in physical connection. The relative positions between the first rod 57 and the second rod 59 may move without affecting the state of the electric connection thereof. By way of the flexible electric connection between the first rod 57 and the second rod 59, after the first rod 57 is stressed, as it may displace relative to the second rod 59 certainly, the resistor body 3 will not be directly affected. Of course, the center shaft conductor 5 may also be flexibly electrically connected to the resistor body 3 directly, and the center shaft conductor 5 may certainly deviate from the resistor body 3 in position without affecting the electric connection with the resistor body 3.

In the embodiment V, the first rod 57 is provided with a mounting groove 571, one end of the second rod 59 is arranged in the mounting groove 571, and the second rod 59 is connected to the resistor body 3. The connecting rod of the first rod 57 and the second rod 59 is equivalent to the connecting mode of a plug and socket electric connector. In the arrangement mode, the sectional area of the first rod 57 is greater than that of the second rod 59, and one end of the second rod 59 may certainly deviate relative to the first rod 57 in position in the mounting groove 571. That is, when the first rod 57 is subjected to the tensile force or the twisting force, no larger force is conducted between the first rod 57 and the second rod 59, and the second rod 59 and the resistor body 3 are connected to achieve conduction of the high-frequency current signal I without damaging the resistor body 3. The second rod 59 matches with the outer conductor 1 to connect the measuring device to measure and display the high-frequency current signal I flowing through the coaxial shunt 10.

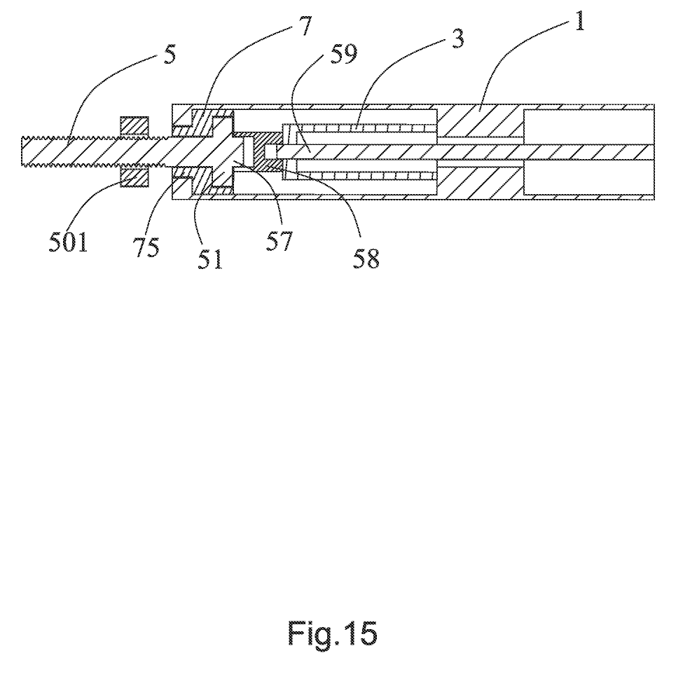

In addition, referring to FIG. 15, FIG. 15 is a sectional view of the coaxial shunt 10 provided in an embodiment VI. In the embodiment VI, the first rod 57 and the second rod 59 are not physically connected directly, a conducting connector 58 is arranged therebetween, and the first rod 57 and the second rod 59 are flexibly electrically connected through the conducting electric connector 58. As the conducting connector 58 is flexibly electrically connected to the first rod 57 and/or the second rod 59, a purpose of protecting the resistor body 3 may be achieved. The connecting solution between the conducting connector 58 and the first rod 57 and the second rod 59 includes various selectable conditions. When the conducting connector 58 is flexibly electrically connected to the first rod 57, the resistor body 3 may not only be connected to conducting connector 58, but also be connected to the second rod 59. When the conducting connector 58 is flexibly electrically connected to the second rod 59, the resistor body 3 may be connected to the second rod 59, which is not specifically limited herein.

In the embodiment, the conducting connector 58 is a conducting elastic metal, for example, a conducting sheet or a wire made from beryllium copper, phosphor copper and the like. The first rod 57 and the second rod 59 and the conducting connector 58 may be connected by way of welding or plugging. As the conducting connector 58 is the elastic metal, it has certain deformability. When the first rod 57 is transferred to the conducting connector 58 when being affected by the external force, the corresponding external force will not be directly transferred to the second rod 59, so that the resistor 3 is protected. Of course, in another embodiment, both ends of the conducting connector 58 are connected to the first rod 57 and the second rod 59, and the resistor body 3 is connected to the conducting connector 58 to play an effect of protecting the resistor body 3 as well. In addition, besides direct connection between the conducting connector 58, and the first rod 57 and the second rod 59, they may also be connected by way of matching with plug and socket electric connection. Various modes are combined in use to protect the resistor body 3.

It is to be noted herein that the flexible electric connection mode between the center shaft conductor 58 and the resistor body 3 may be used independently or combined with the insulating connector 7. In the solutions of the embodiments V and VI, the coaxial shunt 10 is in a mode of combining the two solutions, which has the optimal protective effect on the resistor body 3.

Compared with the prior art, according to the coaxial shunt 10 provided by the present disclosure, the insulating connector 7 is arranged, and moreover, the relative positions of the outer conductor 1 and the center shaft conductor 5 are clamped and fixed. When the coaxial shunt 10 is used, in the operating process, the user will not damage the resistor body 3 inside the outer conductor 5 when pulling or twisting the center shaft conductor 5, thereby ensuring the stable and reliable resistor body 3. And/or the center shaft conductor 5 and the resistor body 3 are flexibly electrically connected to buffer the external force of the center shaft 5 received, which may similarly ensure the stable and effective resistor body 3.

In addition, the insulating connector 7 is simple in overall structure. The gap between the outer conductor 1 and the center shaft conductor 5 is sufficiently utilized without affecting the overall volume of the coaxial shunt 10. The force is transferred when the insulating connector sufficiently fits the outer conductor 1 and the center shaft conductor 5, thereby ensuring the safe and efficient resistor body 3. The flexible electric connection between the center shaft conductor 5 and the resistor body 3 will not increase the overall volume of the coaxial shunt 10, thereby guaranteeing the safe and reliable resistor body 3.

The current detection system 100 using the coaxial shunt 10 prolongs the service life of the product and reduces the replacing frequency of the coaxial shunt 10 while ensuring detection of the precision of the high-frequency current signal I due to the effect of the insulating connector 7, so that the detection cost is reduced.

The above is merely exemplary implementations of the present disclosure. It is to be noted that a person of ordinary skill in the art may make improvements without departing from the concept of the present disclosure and the improvements shall fall within the protection scope of the present disclosure.

What is claimed is:

1. A coaxial shunt, configured to measure a high-frequency current signal in an assisted manner, comprising:
an outer conductor, an accommodating cavity being formed inside the outer conductor;
a resistor body, received in the accommodating cavity;
a central shaft conductor, the outer conductor, the resistor body, and the central shaft conductor each being of cylindrical structures and coaxially arranged from outside to inside, the center shaft conductor penetrating through the outer conductor, and both ends of the resistor body being electrically connected to the outer conductor and the center shaft conductor, respectively; and
an insulating filler, arranged in the accommodating cavity to fill gaps among the outer conductor, the resistor body, and the center shaft conductor, wherein
an insulating connector is arranged between the outer conductor and the central shaft conductor, and the insulating connector is mechanically connected to both the outer conductor and the center shaft conductor to fix relative positions between the center shaft conductor and the outer conductor, and transfers an external force of the center shaft conductor received to the outer conductor;
and/or the center shaft conductor and the resistor body are flexibly electrically connected to buffer the external force of the center shaft received.

2. The coaxial shunt according to claim 1, wherein the center shaft conductor is provided with a first boss, the insulating connector is provided with a base and a first groove, and the first groove is formed relative to the first boss and is formed at a side of the base close to the resistor body.

3. The coaxial shunt according to claim 2, wherein the center shaft conductor penetrates through the base, the first groove matches with the first boss in structural shape, and the first boss is received in the first groove.

4. The coaxial shunt according to claim 2, wherein the external conductor is provided with a locking groove, the insulating connector is provided with a second boss, and the second boss is arranged relative to the clamping groove.

5. The coaxial shunt according to claim 2, wherein the outer conductor is provided with a flange, the insulating connector is provided with a second groove, and the second groove is formed relative to the flange.

6. The coaxial shunt according to claim 1, wherein the center shaft conductor is of a columnar structure, and a thread is arranged at a side of the center shaft conductor stretching out of the outer conductor and matches with a nut to fix a position.

7. The coaxial shunt according to claim 1, wherein the center shaft conductor is provided with a first current conducting rod, the outer conductor is provided with a second current conducting rod, the first current conducting rod is arranged at a side of the center shaft conductor stretching out of the outer conductor, and the second current conducting rod and the first current conducting rod are arranged at an interval at the same side of the outer conductor and each are slender conductors.

8. The coaxial shunt according to claim 1, wherein the center shaft conductor comprises:
a first rod, one end of the first rod stretching out of the outer conductor; and
a second rod, the second rod penetrating through the resistor body and being flexibly electrically connected to the first rod.

9. The coaxial shunt according to claim 8, wherein the first rod is provided with a mounting groove, one end of the second rod is arranged in the mounting groove, and the second rod is electrically connected to the resistor body;
or a conducting connector is arranged between the first rod and the second rod, and the conducting connector is flexibly electrically connected to the first rod and/or the second rod.

10. A current detection system, comprising:
a detection device; and
the coaxial shunt according to claim 1, the detection device being electrically connected to the outer conductor and the center shaft conductor to detect the high-frequency current signal flowing through the outer conductor, the resistor body, and the center shaft conductor.
